(19) United States
(12) Patent Application Publication
(10) Pub. No.: US 2026/0305123 A1
(43) Pub. Date: Oct. 1, 2026

(54) DISPLAY DEVICE

(71) Applicant: ELECTRONICS AND TELECOMMUNICATIONS RESEARCH INSTITUTE, Daejeon (KR)

(72) Inventors: Hyunsu CHO, Daejeon (KR); Kukjoo KIM, Daejeon (KR); Yongduck KIM, Daejeon (KR); CHUNWON BYUN, Daejeon (KR); DAE HYUN AHN, Daejeon (KR); WOOSEUP YOUM, Daejeon (KR); Chul Woong JOO, Daejeon (KR)

(21) Appl. No.: 19/630,079

(22) Filed: Mar. 26, 2026

(30) Foreign Application Priority Data
Mar. 27, 2025 (KR) 10-2025-0039771

(51) Int. Cl. H10K 59/80; H10K 59/38; H10K 102/00; H10K 102/10

(52) U.S. Cl. CPC H10K 59/80518; H10K 59/38; H10K 59/80516; H10K 2102/102; H10K 2102/103; H10K 2102/351

(57) ABSTRACT

The display device includes a substrate comprising a first pixel area and a second pixel area, a first lower electrode on the first pixel area, a second lower electrode on the second pixel area, an upper electrode on the first and second lower electrodes, and a plurality of emission layers between the first and second lower electrodes and the upper electrode. The first lower electrode includes a first reflective electrode on the substrate, and a first injection control electrode on the first reflective electrode, and the second lower electrode includes a second reflective electrode on the substrate, and a second injection control electrode on the second reflective electrode. The first and second injection control electrodes include different materials.

### CROSS-REFERENCE TO RELATED APPLICATION

This U.S. non-provisional patent application claims priority under 35 U.S.C. § 119 of Korean Patent Application No. 10-2025-0039771, filed on Mar. 27, 2025, the entire contents of which are hereby incorporated by reference.

### BACKGROUND

The present disclosure herein relates to a display device, and more particularly, to a display device including an organic light-emitting material.

With the development of the information society, the demand for displays for displaying information is increasing. Thus, various displays such as liquid crystal displays (LCD), electronic paper (e-paper), organic light-emitting displays (OLED), and microdisplays are being developed and utilized.

Currently, virtual reality (VR) and augmented reality (AR) devices are gaining attention as next-generation displays. Since not only image quality but also volume and weight of the display used in the devices are very important, the microdisplays are mainly used. The microdisplays may be broadly classified into liquid crystal on silicon (LCoS), which utilizes liquid crystals, and OLED on Silicon (OLEDoS), which utilizes organic light-emitting diodes (OLEDs). Although the LCoS is applied to various devices, image quality of the LCoS is insufficient for use in AR devices. Thus, recently, interests in the OLEDoS have been increasing.

### SUMMARY

The present disclosure provides a display device having high color purity.

The present disclosure also provides a display device having high resolution.

The object of the present disclosure is not limited to the goal mentioned above, and other objects not described herein will be clearly understood by those skilled in the art from descriptions below.

According to some embodiments of the present disclosure, a display device may include a substrate comprising a first pixel area and a second pixel area, a first lower electrode on the first pixel area, a second lower electrode on the second pixel area, an upper electrode on the first and second lower electrodes, and a plurality of emission layers between the first and second lower electrodes and the upper electrode. The first lower electrode may include a first reflective electrode on the substrate, and a first injection control electrode on the first reflective electrode. The second lower electrode may include a second reflective electrode on the substrate, and a second injection control electrode on the second reflective electrode. The first and second injection control electrodes may include different materials.

In an embodiment, the first reflective electrode and the second reflective electrode may include the same metal as each other.

In an embodiment, the first injection control electrode may include titanium nitride (TiN), and the second injection control electrode may include indium tin oxide (ITO).

In an embodiment, a thickness of the first injection control electrode may be different from a thickness of the second injection control electrode.

In an embodiment, each of the plurality of emission layers may vertically overlap the first and second pixel areas.

In an embodiment, the first reflective electrode and the second reflective electrode may be arranged to be spaced apart from each other, and the first injection control electrode and the second injection control electrode may be arranged to be spaced apart from each other.

In an embodiment, the display device may further include on the first pixel area, a first color filter on the upper electrode; on the second pixel area, a second color filter on the upper electrode, wherein the first color filter and the second color filter may be configured to transmit colors having different bands.

In an embodiment, the first color filter may be a blue color filter configured to selectively transmit blue light, and the second color filter may be a red color filter configured to selectively transmit red light or a green color filter configured to selectively transmit green light.

According to some embodiments of the present disclosure, a display device may include a substrate including a first pixel area, a second pixel area, and a third pixel area, which are sequentially arranged in a first direction, a first lower electrode on the first pixel area; a second lower electrode on the second pixel area, a third lower electrode on the third pixel area; an upper electrode on the first to third lower electrodes, and a plurality of emission layers between the first to third lower electrodes and the upper electrode. The first lower electrode may include a first reflective electrode on the substrate, and a first injection control electrode on the first reflective electrode. The second lower electrode may include a second reflective electrode on the substrate, and a second injection control electrode on the second reflective electrode. The third lower electrode may include a third reflective electrode on the substrate and a third injection control electrode on the third reflective electrode. The first to third injection control electrodes may be arranged to be spaced apart from each other in the first direction.

In an embodiment, the first injection control electrode and the second injection control electrode may include different materials, and the second injection control electrode and the third injection control electrode may include the same material as each other.

In an embodiment, the first injection control electrode may include titanium nitride (TiN), and the second and third injection control electrodes may include indium tin oxide (ITO).

In an embodiment, the plurality of emission layers may include first and second emission layers configured to cover the first to third lower electrodes, respectively, and the first and second emission layers may vertically overlap the first to third pixel areas, respectively.

In an embodiment, the first to third injection control electrodes may include different materials.

In an embodiment, the plurality of emission layers may include first to third emission layers configured to cover the first to third lower electrodes, respectively, and the first to third emission layers may vertically overlap the first to third pixel areas, respectively.

In an embodiment, thicknesses of the first to third injection control electrodes may be different from each other.

In an embodiment, the display device may further include a first color filter on the upper electrode, the first color filter provided on the first pixel area, a second color filter on the upper electrode, the second color filter provided on the second pixel area, and a third color filter on the upper electrode on the third pixel area. The first to third color filters may be configured to transmit colors having different bands.

In an embodiment, the first color filter may be a blue color filter configured to selectively transmit blue light.

In an embodiment, each of the first to third reflective electrodes may include aluminum (Al).

According to some embodiments of the present disclosure, a display device may include a substrate including a first pixel area and a second pixel area, a first lower electrode on the first pixel area; a second lower electrode on the second pixel area, a hole transport layer on the first and second lower electrodes, a plurality of emission layers on the hole transport layer, an electron transport layer on the plurality of emission layers, an upper electrode on the electron transport layer, a thin-film encapsulation layer on the upper electrode, a first color filter on the thin-film encapsulation layer, the first color filter provided on the first pixel area, and a second color filter on the thin-film encapsulation layer, the second color filter provided on the second pixel area. The first lower electrode may include a first reflective electrode on the substrate, and a first injection control electrode on the first reflective electrode. The second lower electrode may include a second reflective electrode on the substrate and a second injection control electrode on the second reflective electrode. The first and second injection control electrodes may include different materials.

In an embodiment, the first color filter may be a blue color filter configured to selectively transmit blue light, the first injection control electrode may include titanium nitride (TiN), and the second injection control electrode may include indium tin oxide (ITO).

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of a display device according to some embodiments of the inventive concept;

FIG. 2 is a cross-sectional view taken along line A-A′ of FIG. 1;

FIG. 3 is an enlarged view of a portion P of FIG. 2;

FIG. 4 is a view illustrating an emission spectrum of generated light according to some embodiments of the inventive concept;

FIG. 5 is a cross-sectional view of a display device according to some embodiments of the inventive concept; and

FIG. 6 is an enlarged view of a portion P of FIG. 5.

### DETAILED DESCRIPTION

In order to sufficiently understand the configuration and effect of the present invention, some embodiments of the present invention will be described with reference to the accompanying drawings. The present disclosure may, however, be embodied in different forms and should not be construed as limited to the embodiments set forth herein. Rather, the exemplary embodiments are provided only to disclose the present invention and let those skilled in the art fully know the scope of the present invention. In the accompanying drawings, the components are shown enlarged for the sake of convenience of explanation, and the proportions of the components may be exaggerated or reduced for clarity of illustration.

Like reference numerals designate like elements throughout the specification.

In the following description, detailed descriptions of configurations and functions that are well known in the technical field of the present invention and are not related to the core configuration of the present invention may be omitted. In this specification, the meanings of the following terms should be understood as follows.

Also, since a shape, a size, a ratio, an angle, a number, etc., which are shown in the accompanying drawings of the present invention are exemplarily illustrated, the present invention is not limited thereto.

Moreover, detailed descriptions related to well-known functions or configurations will be ruled out in order not to unnecessarily obscure subject matters of the present invention.

When ‘comprising’, ‘having’, ‘consisting of’, etc. are used, other components can be added unless ‘only’ is used. Even when a component is explained in singular number they may be interpreted as plural number.

In interpretation of the components, even though separate explicit expressions are not provided, they are to be interpreted as including general tolerance.

When positional relation of two portions is explained by ‘on’, ‘upper’, ‘lower’, ‘beside’, etc., one or more components may be positioned between two portions unless ‘just’ is not used. When portions are connected by ‘or’, the portions are interpreted as including ‘alone’ as well as ‘combination thereof’ but when portions are connected by ‘or’, ‘one of’, portions are interpreted as ‘alone’.

Even though terms such as ‘after’, ‘before’, ‘next to’, ‘and’, ‘herein’, ‘subsequent to’, ‘at this time’, etc. are used, they are not used as limiting temporal position.

It will be understood that although the terms of first and second are used herein to describe various elements, these elements should not be limited by these terms. These terms are only used to distinguish one component from another component. Accordingly, a first component that will be described below may be a second component within the technical idea of the present disclosure.

The term “at least one” should be understood to include all combinations that can be presented from one or more related items. For example, the meaning of “at least one among the first item, the second item, and the third item” may refer not only to each of the first item, the second item, and the third item, but also to all combinations of two or more items among the first item, the second item, and the third item.

Hereinafter, preferred embodiments will be described in detail with reference to the accompanying drawings.

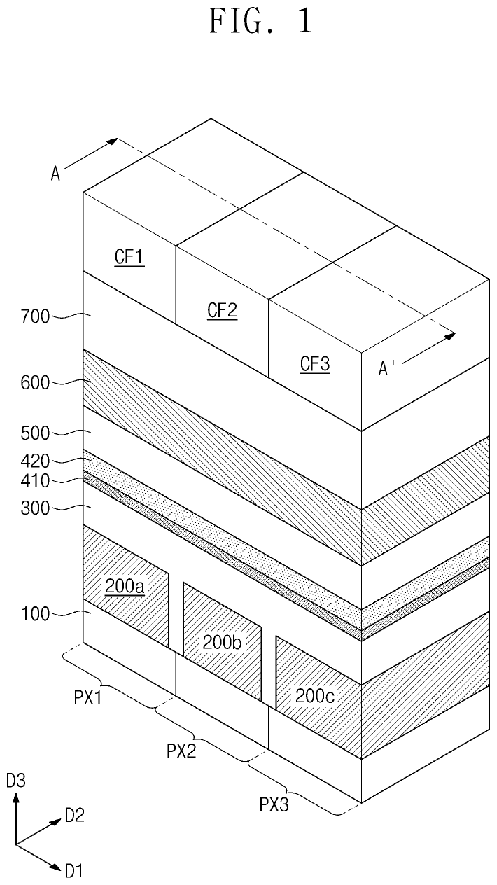

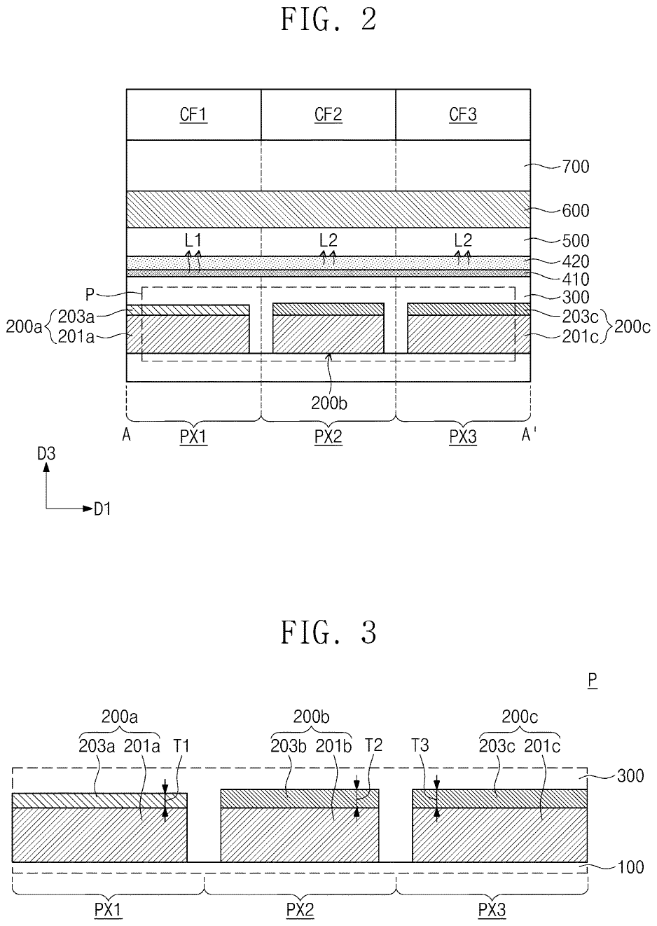

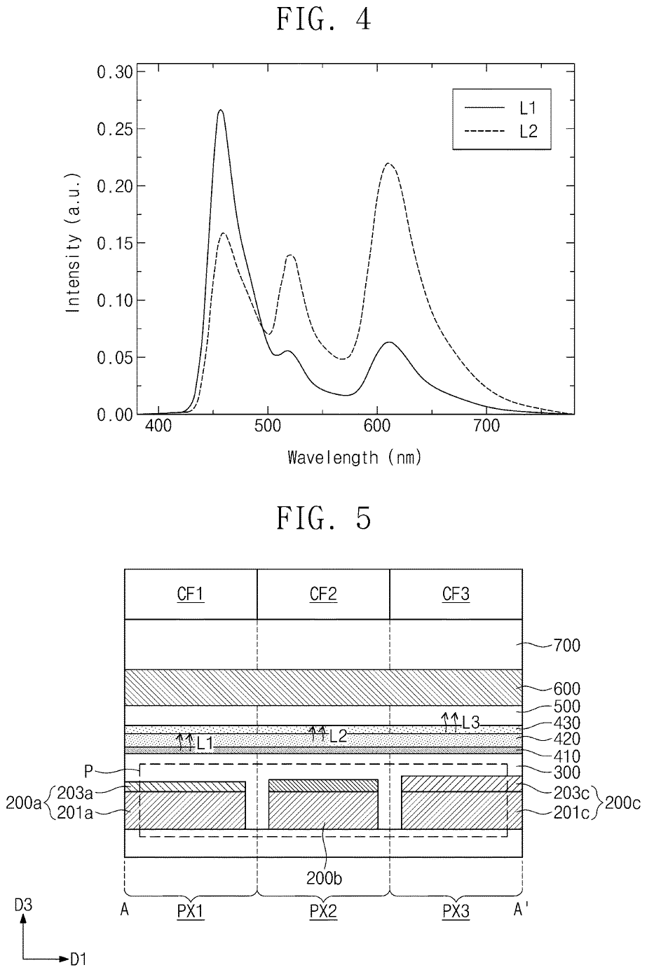

FIG. 1 is a perspective view of a display device according to some embodiments of the inventive concept. FIG. 2 is a cross-sectional view taken along line A-A′ of FIG. 1. FIG. 3 is an enlarged view of a portion P of FIG. 2. FIG. 4 is a view illustrating an emission spectrum of generated light according to some embodiments of the inventive concept.

Referring to FIGS. 1 and 2, a display device may include a substrate 100, first to third lower electrodes 200a, 200b, and 200c, a hole transport layer 300, a plurality of emission layers 410 and 420, an electron transport layer 500, and an upper electrode 600.

The substrate 100 may include first to third pixel areas PX1, PX2, and PX3. For example, the first pixel area PX1, the second pixel area PX2, and the third pixel area PX3 may be sequentially arranged in a first direction D1. The first pixel area PX1 may be an area that emits blue light. The second pixel area PX2 may be an area that emits green light. The third pixel area PX3 may be an area that emits red light. The first direction D1 may be a direction parallel to a top surface of the substrate 100. A second direction D2 may be parallel to a top surface of a base substrate 101 and perpendicular to the first direction D1. A third direction D3 may be a direction perpendicular to the first direction D1 and the second direction D2.

The substrate 100 may be, for example, a silicon substrate. In more details, the substrate 100 may be a substrate in which a semiconductor pattern is disposed on the silicon substrate. For example, the substrate 100 may be a silicon semiconductor substrate provided through a complementary metal oxide semiconductor (CMOS) process. The substrate 100 may include one of a single-crystal silicon wafer, a polycrystalline silicon wafer, and/or an amorphous silicon wafer. For another example, the substrate 100 may include a glass substrate. In more details, the substrate 100 may further include a glass substrate and a thin film transistor (TFT) disposed on the glass substrate.

Although not shown, a circuit layer (not shown) may be provided on the substrate 100. The circuit layer may include conductive lines (not shown) and conductive pads (not shown). Each of the conductive lines and the conductive pads may include a conductive material, for example, a metallic material. The circuit layer may connect the substrate 100 to the first to third lower electrodes 200a, 200b, and 200c described below. In this specification, the term “connected” may include both electrical and physical connection, and may refer to either direct connection or indirect connection via other conductive components.

The first to third lower electrodes 200a, 200b, and 200c may be disposed on the substrate 100. The first to third lower electrodes 200a, 200b, and 200c may be provided to the first to third pixel areas PX1, PX2, and PX3, respectively. For example, the first lower electrode 200a may be provided on the first pixel area PX1, the second lower electrode 200b may be provided on the second pixel area PX2, and the third lower electrode 200c may be provided on the third pixel area PX3. In other words, each of the first to third lower electrodes 200a, 200b, and 200c may be a pixel electrode within the corresponding first to third pixel areas PX1, PX2, and PX3 and may be an anode electrode among the pixel electrodes. The first to third lower electrodes 200a, 200b, and 200c may be arranged to be spaced apart from each other in the first direction D1.

Referring to FIGS. 2 and 3, the first to third lower electrodes 200a, 200b, and 200c may include reflective electrodes 201a, 201b, and 201c and injection control electrodes 203a, 203b, and 203c on the reflective electrodes 201a, 201b, and 201c, respectively. For example, the first lower electrode 200a may include a first reflective electrode 201a and a first injection control electrode 203a disposed on the first reflective electrode 201a. The second lower electrode 200b may include a second reflective electrode 201b and a second injection control electrode 203b disposed on the second reflective electrode 201b. The third lower electrode 200c may include a third reflective electrode 201c and a third injection control electrode 203c disposed on the third reflective electrode 201c.

Each of the first to third reflective electrodes 201a, 201b, and 201c may be a reflective electrode. The first to third reflective electrodes 201a, 201b, and 201c may include substantially the same metal. For example, the first to third reflective electrodes 201a, 201b, and 201c may include at least one of aluminum (Al), copper (Cu), or silver (Ag), and preferably may include aluminum (Al). The first to third reflective electrodes 201a, 201b, and 201c may be arranged to be spaced apart from each other in the first direction D1. Thicknesses of the first to third reflective electrodes 201a, 201b, and 201c may be substantially the same. For example, the thickness of each of the first to third reflective electrodes 201a, 201b, and 201c may refer to a vertical length in the third direction D3.

The first injection control electrode 203a and the second injection control electrode 203b may include different materials. The second injection control electrode 203b and the third injection control electrode 203c may include the same material as each other, but the embodiment of the inventive concept is not limited. For example, the first injection control electrode 203a may include titanium (Ti) and/or titanium nitride (TiN). For example, the second and third injection control electrodes 203b and 203c may include at least one of indium tin oxide (ITO), indium zinc oxide (IZO), fluorine-doped tin oxide (FTO), and transition metal oxide, and preferably may include ITO. For example, the transition metal oxide may include at least one of tungsten (W) or molybdenum (Mo). The first to third injection control electrodes 203a, 203b, and 203c may be arranged to be spaced apart from each other in the first direction D1.

Thicknesses of the second and third injection control electrodes 203b and 203c may be substantially the same. For example, each of the second and third injection control electrodes 203b and 203c may have a second length T2 and a third length T3, respectively, and the second length T2 and the third length T3 may be substantially the same. For example, the thickness of each of the second and third injection control electrodes 201a, 201b, and 201c may refer to a vertical length in the third direction D3.

For example, the thickness of the first injection control electrode 203a may be different from the thicknesses of each of the second and third injection control electrodes 203b and 203c. In other words, the thickness of the first injection control electrode 203a may have a first length T1, and the first length T1 may be different from the second length T2 (or third length T3). For example, the first length T1 may be less than the second length, but the embodiment of the inventive concept is not limited. For another example, the first length T1 may be greater than the second length T2, and for further another example, the first length T1 may be equal to the second length T2.

The first injection control electrode 203a may be disposed on the first reflective electrode 201a to control voltage-current characteristics of holes emitted from the first reflective electrode 201a. In other words, the first injection control electrode 203a may control the voltage-current characteristics of the holes transferred to the hole transport layer 300. The second injection control electrode 203b may be disposed on the second reflective electrode 201b to control voltage-current characteristics of holes emitted from the second reflective electrode 201b. In other words, the second injection control electrode 203b may control the voltage-current characteristics of the holes transferred to the hole transport layer 300. The third injection control electrode 203c may be disposed on the third reflective electrode 201c to control voltage-current characteristics of holes emitted from the third reflective electrode 201c. In other words, the third injection control electrode 203c may control the voltage-current characteristics of the holes transferred to the hole transport layer 300.

According to embodiments of the inventive concept, the first and second injection control electrodes 203a and 203b may include different materials. Since the first and second injection control electrodes 203a and 203b include different materials, the voltage-current characteristics of the holes transferred to the hole transport layer 300 in the first pixel area PX1 may be different from the voltage-current characteristics of the holes transferred to the hole transport layer 300 in the second pixel area PX2.

Referring again to FIG. 2, a hole transport layer 300 may be disposed on the first to third lower electrodes 200a, 200b, and 200c. The hole transport layer 300 may include, for example, at least one of a carbazole derivative such as N-phenylcarbazole, polyvinylcarbazole, N,N′-Di(1-naphthyl)-N,N′-diphenyl-(1,1′-biphenyl)-4,4′ ′-diamine (NPB), N,N′-Bis-(3-methylphenyl)-N,N′-bis-(phenyl)-benzidine (TPD), and N,N′-dinaphthyl-N,N′-diphenyl benzidine (NPD), but the embodiment of the inventive concept is not limited, and may include an organic material that helps the transfer of the holes to the plurality of emission layers 410 and 420. The hole transport layer 300 may further include a first impurity. The first impurity may include a commonly used p-type impurity, and, for example, may include one of 2,3,5,6-fluoro-7,7,8,8-tetracyanoquinodimethane (F4-TCNQ) and NDP-9. For example, in the hole transport layer 300, the first impurity may have a content of about 1 wt % or more and about 3 wt % or less.

The plurality of emission layers 410 and 420 may be provided on the hole transport layer 300. The plurality of emission layers 410, 420 may be provided between the first to third lower electrodes 200a, 200b, and 200c and the upper electrode 600. The plurality of emission layers 410 and 420 may include a first emission layer 410 and a second emission layer 420, which are sequentially laminated on the hole transport layer 300. Each of the plurality of emission layers 410 and 420 may emit light in which blue light, green light, and red light are mixed. In the plurality of emission layers 410 and 420, ratios of the blue light, the green light, and the red light may be different from each other. Each of the plurality of emission layers 410 and 420 may include at least one of a host material or a dopant material. For example, each of the plurality of emission layers 410 and 420 may be provided by using a phosphorescent or fluorescent emitting material as a dopant in a host material. Each of the plurality of emission layers 410 and 420 may vertically overlap the first to third lower electrodes 200a, 200b, and 200c. That is, the plurality of emission layers 410 and 420 may cover the first to third lower electrodes 200a, 200b, and 200c.

In the first emission layer 410,the holes emitted from the first pixel area PX1 may be transferred to generate light (or photons), and in the second emission layer 420, the holes emitted from the second and third pixel areas PX2 and PX3 may be transferred to generate light (or photons). That is, the holes passing through the first injection control electrode 203a may be transferred to the first emission layer 410, and the holes passing through the second and third injection control electrodes 203b and 203c may be transferred to the second emission layer 420. Referring to FIG. 2, although the second emission layer 420 is disposed on the first emission layer 410, the embodiment of the inventive concept is not limited, and the first emission layer 410 may be disposed on the second emission layer 420. This may vary depending on the material and thickness of each of the first to third injection control electrodes 203a, 203b, and 203c.

Referring to FIGS. 2 and 4, in the plurality of emission layers 410 and 420, the voltage-current characteristics of the holes used for the photon generation may be different from each other. Thus, an emission spectrum of light L1 generated in the first emission layer 410 may be different from an emission spectrum of light L2 generated in the second emission layer 420.

For example, the light L1 generated in the first emission layer 410 may have the highest intensity in a wavelength range of 400 nm or more to 500 nm or less. That is, an intensity of the blue light among the light L1 generated in the first emission layer 410 may be relatively greater than an intensity of the green light or the red light. When the intensity of the blue light is relatively high on the first pixel area PX1, a color purity of a blue color discharged onto a first color filter CF1 may increase.

For example, the light L2 generated in the second emission layer 420 may have the highest intensity in a wavelength range of 600 nm or more to 700 nm or less and a wavelength range of about 500 nm or more to about 550 nm or less. That is, an intensity of each of the red light and the green light, which are generated in the second emission layer 420, may be relatively greater than an intensity of the blue light. When the intensity of the green light (or the red light) is relatively high on the second pixel area PX2, a color purity of a green (or red) color emitted onto a second color filter CF2 may increase. When the intensity of the red light (or the green light) is relatively high on the third pixel area PX3, a color purity of a red (or green) color emitted through the third color filter CF3 may increase.

According to embodiments of the inventive concept, when the same driving voltage is applied to the first to third lower electrodes 200a, 200b, and 200c, the emission spectra of the light generated may vary depending on the first to third pixel areas PX1, PX2, and PX3. In other words, the intensities of the blue light, the green light, and the red light vary within white light for each of the pixel areas PX1, PX2, and PX3, a color purity of monochromatic light on each of the pixel areas PX1, PX2, and PX3 may increase. Thus, a display device having high color purity may be provided.

In addition, according to embodiments of the inventive concept, the corresponding color purity may be high on each of the pixel areas PX1, PX2, and PX3 regardless of a magnitude of the driving voltage. In other words, light having an emission spectra corresponding to each of the pixel areas PX1, PX2, and PX3 may be generated, and at least partially, a change in color purity due to the magnitude of the driving voltage may be prevented. Thus, a display device having high resolution may be provided.

Referring again to FIGS. 1 and 2, the electron transport layer 500 may be disposed on the plurality of emission layers 410 and 420. The electron transport layer 500 may transfer electrons emitted from the upper electrode 600 described below to the plurality of emission layers 410 and 420. For example, the electron transport layer 500 may include at least one of 2-(4-biphenyl)-5-(4-tert-butylphenyl)-1,3,4-oxadiazole (PBD) or 3-phenyl-4-(1-naphthyl)-5-phenyl-1,2,4-triazole (TAZ), but the embodiment of the inventive concept is not limited, and may include an organic material that helps the transfer of the electrons to the plurality of emission layers 410 and 420.

The upper electrode 600 may be disposed on the electron transport layer 500. The upper electrode 600 may provide electrons that move toward the electron transport layer 500. The upper electrode 600 may serve as a common electrode and may perform the role of a cathode. For example, the upper electrode 600 may include at least one of a transparent conductive material (TCO) such as ITO or IZO that transmits light, or a semi-transmissive conductive material such as magnesium (Mg), silver (Ag), or an alloy of magnesium (Mg) and silver (Ag).

A thin-film encapsulation layer 700 may be provided on the upper electrode 600. The thin-film encapsulation layer 700 may include a single inorganic layer (not shown) or a first inorganic layer (not shown), an organic layer (not shown), and a second inorganic layer (not shown), which are sequentially laminated. The organic layer may be disposed between the first inorganic layer and the second inorganic layer. The first inorganic layer and the second inorganic layer may be provided by depositing an inorganic material, and the organic layer may be provided by depositing, printing, or coating an organic material. The inorganic layer (a single inorganic layer, a first inorganic layer, and a second inorganic layer) may protect the organic emission layer from moisture and oxygen, and the organic layer may protect the organic emission layer from foreign substances such as dust particles.

A first to third color filters CF1 to CF3 may be disposed on the thin-film encapsulation layer 700. The first color filter CF1, the second color filter CF2, and the third color filter CF3 may be arranged to be spaced apart from each other in the first direction D1. The first color filter CF1, the second color filter CF2, and the third color filter CF3 may be disposed within the first pixel area PX1, the second pixel area PX2, and the third pixel area PX3, respectively. The first to third color filters CF1, CF2, and CF3 may transmit colors having different bands. For example, the first color filter CF1 may be a blue color filter, which transmits light in the wavelength range of the blue light and absorbs light having wavelength ranges of other colors. For example, the second color filter CF2 may be a green color filter, which transmits light in the wavelength range of the green light and absorbs light having wavelength ranges of other colors. For example, the third color filter CF3 may be a red color filter, which transmits light in the wavelength range of the red light and absorbs light having wavelength ranges of other colors. Although not shown, a pixel isolation layer may be provided between the first color filter CF1, the second color filter CF2, and the third color filter CF3, and a protective layer (not shown) and a sub substrate (not shown) may be further provided on the first color filter CF1, the second color filter CF2, and the third color filter CF3.

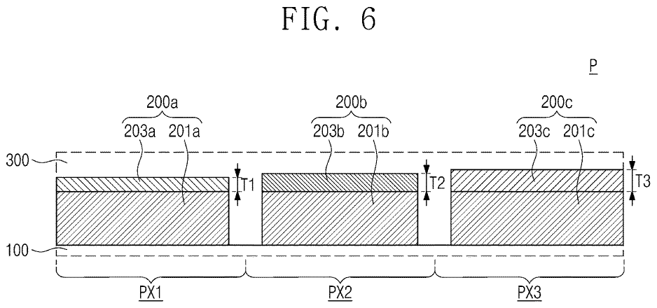

FIG. 5 is a cross-sectional view of a display device according to some embodiments of the inventive concept. FIG. 6 is an enlarged view of a portion P of FIG. 5. For simplifying the description, contents that are repeated from the descriptions provided with reference to FIGS. 1 to 4 are omitted.

Referring to FIGS. 5 and 6, a display device may include a substrate 100, first to third lower electrodes 200a, 200b, and 200c, a hole transport layer 300, a plurality of emission layers 410 and 420, an electron transport layer 500, and an upper electrode 600.

The first lower electrode 200a may include a first reflective electrode 201a and a first injection control electrode 203a disposed on the first reflective electrode 201a. The second lower electrode 200b may include a second reflective electrode 201b and a second injection control electrode 203b disposed on the second reflective electrode 201b. The third lower electrode 200c may include a third reflective electrode 201c and a third injection control electrode 203c disposed on the third reflective electrode 201c.

Each of the first to third reflective electrodes 201a, 201b, and 201c may be a reflective electrode. The first to third reflective electrodes 201a, 201b, and 201c may include substantially the same metal.

The first to third injection control electrodes 203a, 203b, and 203c may include different materials. For example, the first injection control electrode 203a may include titanium (Ti) and/or titanium nitride (TiN). For example, the second injection control electrode 203b may include one of indium tin oxide (ITO), indium zinc oxide (IZO), fluorine-doped tin oxide (FTO), and transition metal oxide. The third injection control electrode 203c may include one of indium tin oxide (ITO), indium zinc oxide (IZO), fluorine-doped tin oxide (FTO), and transition metal oxide, but may include a material different from that of the second injection control electrode 203b. The first to third injection control electrodes 203a, 203b, and 203c may be arranged to be spaced apart from each other in the first direction D1.

Thicknesses of the first to third injection control electrodes 203a, 203b, and 203c may be different from each other. For example, the first to third injection control electrodes 203a, 203b, and 203c may have a first length T1, a second length T2, and a third length T3, respectively, and the first to third lengths T1, T2, and T3 may be different from each other. For example, the first length T1 may be less than the second length T2, and the second length T2 may be less than the third length T3, but the embodiment of the inventive concept is not limited. For another example, the first length T1 may be greater than the second length T2, and the second length T2 may be greater than the third length T3. As another example, the first to third lengths T1, T2, and T3 may be substantially the same as each other.

The first injection control electrode 203a may be disposed on the first reflective electrode 201a to control voltage-current characteristics of holes emitted from the first reflective electrode 201a. In other words, the first injection control electrode 203a may control the voltage-current characteristics of the holes transferred to the hole transport layer 300. The second injection control electrode 203b may be disposed on the second reflective electrode 201b to control voltage-current characteristics of holes emitted from the second reflective electrode 201b. In other words, the second injection control electrode 203b may control the voltage-current characteristics of the holes transferred to the hole transport layer 300. The third injection control electrode 203c may be disposed on the third reflective electrode 201c to control voltage-current characteristics of holes emitted from the third reflective electrode 201c. In other words, the third injection control electrode 203c may control the voltage-current characteristics of the holes transferred to the hole transport layer 300.

A plurality of emission layers 410, 420, and 430 may be provided on the hole transport layer 300. The plurality of emission layers 410 and 420 may include a first emission layer 410, a second emission layer 420, and a third emission layer 430, which are sequentially laminated on the hole transport layer 300. The plurality of emission layers 410, 420, and 430 may emit light including blue light, green light, and red light, respectively. In the plurality of emission layers 410 and 420, ratios of the blue light, the green light, and the red light may be different from each other. Each of the plurality of emission layers 410, 420, and 430 may include at least one of a host material or a dopant material. Each of the plurality of emission layers 410 and 420,430 may vertically overlap the first to third lower electrodes 200a, 200b, and 200c.

In the first emission layer 410, holes emitted from the first pixel area PX1 may be transferred to generate light (or photons), and in the second emission layer 420, holes emitted from the second pixel area PX2 may be transferred to generate light (or photons). In the third emission layer 430, holes emitted from the third pixel area PX3 may be transferred to generate light (or photons). That is, the holes passing through the first injection control electrode 203a may be transferred to the first emission layer 410, the holes passing through the injection control electrode 203b may be transferred to the second emission layer 420, and the holes passing through the third injection control electrode 203c may be transferred to the third emission layer 430. Referring to FIG. 5, although the second emission layer 420 and the third emission layer 430 are disposed on the first emission layer 410, the embodiment of the inventive concept is not limited. For example, the arrangement order of the first to third emission layers 410, 420, and 430 may vary depending on the material and thickness of each of the first to third injection control electrodes 203a, 203b, and 203c.

In the plurality of emission layers 410, 420, and 430, voltage-current characteristics of the hole used for the photon generation may be different from each other. In other words, within the first to third emission layers 410, 420, and 430, the voltage-current characteristics of the hole used for the photon generation may differ from each other. Thus, an emission spectrum of the light generated in the first emission layer 410 may be different from an emission spectrum of the light generated in the second emission layer 420 and also may be different from an emission spectrum of the light generated in the third emission layer 430.

An intensity of the blue light among the light L1 generated in the first emission layer 410 may be relatively greater than an intensity of the green light or the red light. On the first pixel area PX1, since the intensity of the blue light of the generated light L1 is relatively high, a color purity of a blue color emitted onto the first color filter CF1 may increase.

An intensity of the green light generated in the second emission layer 420 may be relatively greater than an intensity of the red light or blue light. On the second pixel area PX2, since the intensity of the green light of the generated light L2 is relatively high, a color purity of a green color emitted onto the second color filter CF2 may increase.

An intensity of the red light of the light L3 generated in the third emission layer 430 may be relatively greater than an intensity of the green or blue light. In the third pixel area PX3, since the intensity of the red light of the generated light L3 is relatively high, a color purity of a red color emitted onto the third color filter CF3 may increase.

In the display device according to the inventive concept, each of the lower electrodes disposed on the pixel areas may include the reflective electrode and the injection control electrode disposed on the reflective electrode. The injection control electrode may control the emission spectrum of the light generated on the pixel area. As a result, the intensity of the light having the desired color (e.g., red light, blue light, or green light) may be adjusted to increase within each pixel area, thereby improving the color purity. Furthermore, the display device having the high color purity and the high resolution may be provided.

Although embodiments of the present invention have been described above with reference to the attached drawings, the present invention may be implemented in other specific forms without changing the technical idea or essential features. Therefore, the embodiments described above should be understood as illustrative in all respects and not restrictive.

What is claimed is:

1. A display device comprising:
a substrate including a first pixel area and a second pixel area;
a first lower electrode on the first pixel area;
a second lower electrode on the second pixel area;
an upper electrode on the first and second lower electrodes; and
a plurality of emission layers between the first and second lower electrodes and the upper electrode,
wherein the first lower electrode comprises:
a first reflective electrode on the substrate; and
a first injection control electrode on the first reflective electrode,
wherein the second lower electrode comprises:
a second reflective electrode on the substrate; and
a second injection control electrode on the second reflective electrode,
wherein the first and second injection control electrodes include different materials.

2. The display device of claim 1, wherein the first reflective electrode and the second reflective electrode include the same metal as each other.

3. The display device of claim 1, wherein the first injection control electrode includes titanium nitride (TiN), and
the second injection control electrode includes indium tin oxide (ITO).

4. The display device of claim 1, wherein a thickness of the first injection control electrode is different from a thickness of the second injection control electrode.

5. The display device of claim 1, wherein each of the plurality of emission layers vertically overlaps the first and second pixel areas.

6. The display device of claim 1, wherein the first reflective electrode and the second reflective electrode are spaced apart from each other, and
wherein the first injection control electrode and the second injection control electrode are spaced apart from each other.

7. The display device of claim 1, further comprising:
a first color filter on the upper electrode, the first color filter provided on the first pixel area; and
a second color filter on the upper electrode, the second color filter provided on the second pixel area,
wherein the first color filter and the second color filter are configured to transmit colors having different bands.

8. The display device of claim 7, wherein the first color filter is a blue color filter configured to selectively transmit blue light, and
wherein the second color filter is a red color filter configured to selectively transmit red light or a green color filter configured to selectively transmit green light.

9. A display device comprising:
a substrate including a first pixel area, a second pixel area, and a third pixel area, which are sequentially arranged in a first direction;
a first lower electrode on the first pixel area;
a second lower electrode on the second pixel area;
a third lower electrode on the third pixel area;
an upper electrode on the first to third lower electrodes; and
a plurality of emission layers between the first to third lower electrodes and the upper electrode,
wherein the first lower electrode comprises:
a first reflective electrode on the substrate; and
a first injection control electrode on the first reflective electrode,
wherein the second lower electrode comprises:
a second reflective electrode on the substrate; and
a second injection control electrode on the second reflective electrode,
wherein the third lower electrode comprises:
a third reflective electrode on the substrate; and
a third injection control electrode on the third reflective electrode,
wherein the first to third injection control electrodes are spaced apart from each other in the first direction.

10. The display device of claim 9, wherein the first injection control electrode and the second injection control electrode include different materials, and
wherein the second injection control electrode and the third injection control electrode include the same material as each other.

11. The display device of claim 10, wherein the first injection control electrode includes titanium nitride (TiN), and
wherein the second and third injection control electrodes include indium tin oxide (ITO).

12. The display device of claim 10, wherein the plurality of emission layers comprise first and second emission layers configured to cover the first to third lower electrodes, respectively, and
wherein the first and second emission layers vertically overlap the first to third pixel areas, respectively.

13. The display device of claim 9, wherein the first to third injection control electrodes include different materials.

14. The display device of claim 13, wherein the plurality of emission layers include first to third emission layers configured to cover the first to third lower electrodes, respectively, and
wherein the first to third emission layers vertically overlap the first to third pixel areas, respectively.

15. The display device of claim 13, wherein thicknesses of the first to third injection control electrodes are different from each other.

16. The display device of claim 9, further comprising:
a first color filter on the upper electrode, the first color filter provided on the first pixel area;
a second color filter on the upper electrode, the second color filter provided on the second pixel area; and
a third color filter on the upper electrode, the third color filter provided on the third pixel area,
wherein the first to third color filters are configured to transmit colors having different bands.

17. The display device of claim 16, wherein the first color filter is a blue color filter configured to selectively transmit blue light.

18. The display device of claim 9, wherein each of the first to third reflective electrodes includes aluminum (Al).

19. A display device comprising:
a substrate including a first pixel area and a second pixel area;
a first lower electrode on the first pixel area;
a second lower electrode on the second pixel area;
a hole transport layer on the first and second lower electrodes;
a plurality of emission layers on the hole transport layer;
an electron transport layer on the plurality of emission layers;
an upper electrode on the electron transport layer;
a thin-film encapsulation layer on the upper electrode;
a first color filter on the thin-film encapsulation layer, the first color filter provided on the first pixel area; and
a second color filter on the thin-film encapsulation layer, the second color filter provided on the second pixel area,
wherein the first lower electrode comprises:
a first reflective electrode on the substrate; and
a first injection control electrode on the first reflective electrode,
wherein the second lower electrode comprises:
a second reflective electrode on the substrate; and
a second injection control electrode on the second reflective electrode,
wherein the first and second injection control electrodes include different materials.

20. The display device of claim 19, wherein the first color filter is a blue color filter configured to selectively transmit blue light,
wherein the first injection control electrode includes titanium nitride (TiN), and
wherein the second injection control electrode includes indium tin oxide (ITO).
